(19) United States
(12) Patent Application Publication
(10) Pub. No.: US 2020/0388709 A1
(43) Pub. Date: Dec. 10, 2020

(54) THIN FILM TRANSISTOR, METHOD FOR MANUFACTURING SAME, AND DISPLAY APPARATUS

(71) Applicant: SAKAI DISPLAY PRODUCTS CORPORATION, Osaka (JP)

(72) Inventor: HIROYUKI OHTA, Osaka (JP)

(21) Appl. No.: 16/833,139

(22) Filed: Mar. 27, 2020

Related U.S. Application Data
(60) Provisional application No. 62/859,478, filed on Jun. 10, 2019.

(51) Int. Cl. H01L 29/786; H01L 27/12; H01L 29/49; H01L 29/66; H01L 21/4757

(52) U.S. Cl. CPC H01L 29/7869; H01L 27/1248; H01L 29/4908; H01L 29/4991; G09G 3/3233; H01L 29/66969; H01L 27/1288; H01L 21/47573; G09G 2320/0257; H01L 27/1225

(57) ABSTRACT

A thin film transistor includes: an oxide semiconductor layer including a first region, a second region, and a channel region located between the first region and the second region; a gate electrode provided on the channel region with a gate insulating layer interposed therebetween; a source electrode electrically coupled with the first region; a drain electrode electrically coupled with the second region; and an upper insulating layer covering the oxide semiconductor layer and the gate electrode, wherein when viewed in a normal direction of the substrate, the gate electrode overlaps the channel region of the oxide semiconductor layer but overlaps none of the first region and the second region, a lateral surface of the gate electrode includes a first lateral surface portion located on the first region side and overlapping the oxide semiconductor layer and a second lateral surface portion located on the second region side and overlapping the oxide semiconductor layer, the upper insulating layer includes a first fringe region which is located in a vicinity of the first lateral surface portion of the gate electrode when viewed in the normal direction of the substrate and whose height from an upper surface of the oxide semiconductor layer is smaller than a height of an upper surface of the gate electrode, and a second fringe region which is located in a vicinity of the second lateral surface portion of the gate electrode when viewed in the normal direction of the substrate and whose height from the upper surface of the oxide semiconductor layer is smaller than the height of the upper surface of the gate electrode, the upper insulating layer includes a porous insulator layer, the porous insulator layer including a first portion located in the first fringe region and a second portion located in the second fringe region, and the first portion of the porous insulator layer is in contact with at least part of the first region of the oxide semiconductor layer, and the second portion of the porous insulator layer is in contact with at least part of the second region of the oxide semiconductor layer.

### BACKGROUND

### 1. Technical Field

The present invention relates to a thin film transistor and a method for manufacturing the same, and a display apparatus.

### 2. Description of the Related Art

Active matrix substrates are used in, for example, display apparatuses such as liquid crystal display apparatuses, organic EL (Electro Luminescence) display apparatuses, and micro LED (Light Emitting Diode) display apparatuses. The micro LED display apparatuses include a plurality of light-emitting diodes (LED) which are made of inorganic compounds and which are two-dimensionally arrayed.

In each pixel of an active matrix substrate, a circuit (which is referred to as “pixel circuit”) is provided which includes a thin film transistor (hereinafter, “TFT”). In current-driven display apparatuses such as micro LED display apparatuses and organic EL display apparatus, for example, light emitting devices (LEDs, organic EL devices, etc.) whose emission luminance varies according to the current are provided so as to correspond to respective pixels. The electric current supplied to the light emitting device of each pixel is controlled by a pixel circuit.

In some active matrix substrates, a peripheral circuit such as a driving circuit is monolithically provided. TFTs can also be used as circuit elements in the peripheral circuit.

In this specification, TFTs used in the pixel circuit are referred to as “pixel circuit TFTs”, and TFTs which are constituents of the peripheral circuit are referred to as “peripheral circuit TFTs”.

TFTs widely used in active matrix substrates are, traditionally, amorphous silicon TFTs in which an amorphous silicon film (hereinafter, referred to as “a-Si film”) is used as the active layer and polycrystalline silicon TFTs in which a polycrystalline silicon (polysilicon) film (hereinafter, referred to as “poly-Si film”) is used as the active layer. Instead of these silicon TFTs, TFTs which include an oxide semiconductor such as In—Ga—Zn—O based semiconductor (hereinafter, referred to as “oxide semiconductor TFTs”) are sometimes used.

For example, Japanese Laid-Open Patent Publication No. 2015-056566 and Japanese Laid-Open Patent Publication No. 2011-187506 disclose using oxide semiconductor TFTs which have a top gate configuration as the pixel circuit TFTs. Japanese Laid-Open Patent. Publication No. 2015-056566 suggests arranging the gate, source and drain electrodes with the use of a self-alignment technique such that the gate electrode overlaps none of the source electrode and the drain electrode, thereby reducing the parasitic capacitance of the oxide semiconductor TFT.

### SUMMARY

TFTs used in the pixel circuits and the peripheral circuits are required to have further reduced parasitic capacitance in some cases.

For example, in a current-driven display apparatus, if a pixel circuit TFT has large parasitic capacitance, switching of the pixel circuit TFT from ON to OFF causes accumulated charge which is present in the parasitic capacitance to be supplied to a light emitting device which is to be turned off. As a result, the lighting operation of the light emitting device which is to be turned off continues for a while, and there is a probability that display failure called “ghosting” will occur.

If peripheral circuit TFTs which are constituents of peripheral circuits have large parasitic capacitance, there is a probability that the large parasitic capacitance will cause decrease in operation speed of the peripheral circuits and increase in power consumption.

However, according to research by the present inventors, conventional TFT structures (for example, Japanese Laid-Open Patent Publication No. 2015-056566 and Japanese Laid-Open Patent Publication No. 2011-187506) have difficulty in further reducing the parasitic capacitance.

One embodiment of the present invention was conceived in view of the foregoing circumstances. An object of the present invention is to provide a thin film transistor which is capable of reducing the parasitic capacitance and a manufacturing method thereof, and a display apparatus which includes the thin film transistor.

[Item 1]

A thin film transistor comprising:

a substrate;

an oxide semiconductor layer supported by the substrate, the oxide semiconductor layer including a first region, a second region, and a channel region located between the first region and the second region;

a gate electrode provided on the channel region of the oxide semiconductor layer with a gate insulating layer interposed therebetween;

a source electrode electrically coupled with the first region of the oxide semiconductor layer;

a drain electrode electrically coupled with the second region of the oxide semiconductor layer; and
an upper insulating layer covering the oxide semiconductor layer, the gate insulating layer and the gate electrode, wherein
when viewed in a normal direction of the substrate, the gate electrode overlaps the channel region of the oxide semiconductor layer but overlaps none of the first region and second region,
when viewed in the normal direction of the substrate, a lateral surface of the gate electrode includes a first lateral surface portion located on the first region side and overlapping the oxide semiconductor layer and a second lateral surface portion located on the second region side and overlapping the oxide semiconductor layer,
the upper insulating layer includes
   a first fringe region which is located in a vicinity of the first lateral surface portion of the gate electrode when viewed in the normal direction of the substrate and whose height from an upper surface of the oxide semiconductor layer is smaller than a height of an upper surface of the gate electrode, and
   a second fringe region which is located in a vicinity of the second lateral surface portion of the gate electrode when viewed in the normal direction of the substrate and whose height from the upper surface of the oxide semiconductor layer is smaller than the height of the upper surface of the gate electrode,
the upper insulating layer includes a porous insulator layer, the porous insulator layer including a first portion located in the first fringe region and a second portion located in the second fringe region, and
the first portion of the porous insulator layer is in contact with at least part of the first region of the oxide semiconductor layer, and the second portion of the porous insulator layer is in contact with at least part of the second region of the oxide semiconductor layer.

[Item 2]

The thin film transistor of Item 1, wherein the gate insulating layer includes a silicon oxide layer.

[Item 3]

The thin film transistor of Item 1 or 2, wherein a relative permittivity at the frequency of 1 MHz of the porous insulator layer is not more than 3.0.

[Item 4]

The thin film transistor of any of Items 1 to 3, wherein the first portion of the porous insulator layer is in contact with the first lateral surface portion of the gate electrode, and the second portion of the porous insulator layer is in contact with the second lateral surface portion of the gate electrode.

[Item 5]

The thin film transistor of any of items 1 to 4 wherein, when viewed in the normal direction of the substrate, a lateral surface of the gate insulating layer and the lateral surface of the gate electrode are aligned.

[Item 6]

The thin film transistor of Item 5, wherein the porous insulator layer is in contact with the lateral surface of the gate insulating layer.

[Item 7]

The thin film transistor of any of Items 1 to 4 wherein, when viewed in the normal direction of the substrate, a lateral surface of the gate insulating layer is more internal than the lateral surface of the gate electrode.

[Item 8]

The thin film transistor of Item 7, wherein at least part of the porous insulator layer is located between the gate electrode and the channel region so as to be in contact with the lateral surface of the gate insulating layer

[Item 9]

The thin film transistor of Item 7, wherein there is an air gap provided between the gate electrode and the channel region and between the lateral surface of the gate insulating layer and the upper insulating layer.

[Item 10]

The thin film transistor of any of Items 1 to 9, wherein the upper insulating layer includes non-porous insulator layer provided on the porous insulator layer.

[Item 11]

The thin film transistor of Item 10, wherein
the upper insulating layer includes a first insulating portion which includes the first fringe region and the second fringe region and a second insulating portion which lies outside the first insulating portion when viewed in the normal direction of the substrate,

the first insulating portion includes the porous insulator layer and the non-porous insulator layer, and the second insulating portion includes the non-porous insulator layer but does not include the porous insulator layer, and

the second insulating portion has a first opening for connecting the source electrode with the first region and a second opening for connecting the drain electrode with the second region.

[Item 12]

The thin film transistor of any of Items 1 to 10, wherein a thickness of the porous insulator layer is not less than a thickness of the gate electrode.

[Item 13]

The thin film transistor of any of Items 1 to 12, wherein the porous is layer formed by an organic SOG film or an inorganic SOG film.

[Item 14]

The thin film transistor of any of Items 1 to 13, wherein

the first region of the oxide semiconductor layer has at its surface a first low-resistance region whose specific resistance is smaller than that of the channel region, and the second region of the oxide semiconductor layer has at its surface a second low-resistance region whose specific resistance is smaller than that of the channel region, and

the first portion of the porous insulator layer is in contact with at least part of the first low-resistance region, and the second portion of the porous insulator layer is in contact with at least part of the second low-resistance region.

[Item 15]

A display apparatus comprising:

the thin film transistor as set forth in any of Items 1 to 14;

a display region which has a plurality of pixels; and

a pixel circuit arranged so as to correspond to respective ones of the plurality of pixels,

wherein the pixel circuit includes the thin film transistor.

[Item 16]

The display apparatus of Item 15, further comprising a current-driven light emitting device arranged so as to correspond to respective ones of the plurality of pixels, wherein the pixel circuit drives the light emitting device.

[Item 17]

A manufacturing method of a thin film transistor supported by a substrate, the method comprising steps of:

(A) forming an oxide semiconductor layer on the substrate;

(B) forming a gate insulating layer and a gate electrode in this order on part of the oxide semiconductor layer; and

(C) forming an upper insulating layer so as to cover the oxide semiconductor layer, the gate insulating layer and the gate electrode, the upper insulating layer including a porous insulator layer,

wherein the upper insulating layer includes
a first fringe region which is located in a vicinity of a first lateral surface portion of the gate electrode when viewed in a normal direction of the substrate and whose height from an upper surface of the oxide semiconductor layer is smaller than a height of an upper surface of the gate electrode and
a second fringe region which is located in a vicinity of a second lateral surface portion of the gate electrode when viewed in the normal direction of the substrate and whose height from the upper surface of the oxide semiconductor layer is smaller than the height of the upper surface of the gate electrode,

the porous insulator layer includes a first portion located in the first fringe region and a second portion located in the second fringe region, and each of the first portion and the second portion of the porous insulator layer is in contact with part of the oxide semiconductor layer which is not covered with the gate insulating layer, and

the step (B) includes steps of
(B1) forming an insulative film and an electrically-conductive gate film in this order on the oxide semiconductor layer,
(B2) patterning the electrically-conductive gate film using a first mask, thereby forming the gate electrode, and
(B3) after the step (B2), patterning the insulative film using the first mask or using the gate electrode as a mask, thereby forming the gate insulating layer, a lateral surface of the gate insulating layer being more internal than a lateral surface of the gate electrode when viewed in the normal direction of the substrate.

[Item 18]

The method of Item 17, wherein the step (B3) includes performing isotropic etching of the insulative film using the first mask or using the gate electrode as a mask, thereby forming the gate insulating layer.

[Item 19]

The method of Item 11, wherein the step (B3) includes

(B4) performing isotropic etching on the insulative film using the first mask or using the gate electrode as a mask, thereby forming a gate insulating layer precursor, and

(B5) etching a lateral surface of the gate insulating layer precursor, thereby forming the gate insulating layer.

[Item 20]

The method of any of Items 17 to 19, wherein the step (C) includes forming the porous insulator layer so as to be in contact with the lateral surface of the gate Insulating layer.

[Item 21]

The method of any of Items 17 to 20, wherein the step (C) includes applying a SOG solution and performing drying and a heat treatment of a resultant SOG film, thereby forming the porous insulator layer.

According to one embodiment of the present invention, a thin film transistor which is capable of reducing the parasitic capacitance and a manufacturing method thereof, and a display apparatus which includes the thin film transistor are provided.

### BRIEF DESCRIPTION OF THE DRAWINGS

FIG. 1A is a schematic cross-sectional view of a TFT 101 of an embodiment.

FIG. 1B is a schematic plan view of the TFT 101 of the embodiment.

FIG. 2A is a stepwise cross-sectional view for illustrating a manufacturing method of the TFT 101.

FIG. 2B is a stepwise cross-sectional view for illustrating the manufacturing method of the TFT 101.

FIG. 2C is a stepwise cross-sectional view for illustrating the manufacturing method of the TFT 101.

FIG. 2D is a stepwise cross-sectional view for illustrating the manufacturing method of the TFT 101.

FIG. 2E is a stepwise cross-sectional view for illustrating the manufacturing method of the TFT 101.

FIG. 3A is a cross-sectional view illustrating a TFT 102 of Variation 1.

FIG. 3B is a cross-sectional view illustrating another TFT 103 of Variation 1.

FIG. 4A is a stepwise cross-sectional view for illustrating a manufacturing method of the TFT 102.

FIG. 4B is a stepwise cross-sectional view for illustrating the manufacturing method of the TFT 102.

FIG. 4C is a stepwise cross-sectional view for illustrating the manufacturing method of the TFT 102.

FIG. 5A is a cross-sectional view illustrating a TFT 104 of Variation 2.

FIG. 5B is a cross-sectional view illustrating another TFT 105 of Variation 2.

FIG. 5C is a cross-sectional view illustrating still another TFT 106 of Variation 2.

FIG. 6 is a schematic cross-sectional view for illustrating the first and second fringe regions FR1, FR2.

FIG. 7 is a cross-sectional view of a TFT 900 of a reference example.

### DETAILED DESCRIPTION

### Embodiment

Hereinafter, a TFT of an embodiment is described with reference to the drawings, with an example of an oxide semiconductor TFT which includes an oxide semiconductor layer as the active layer.

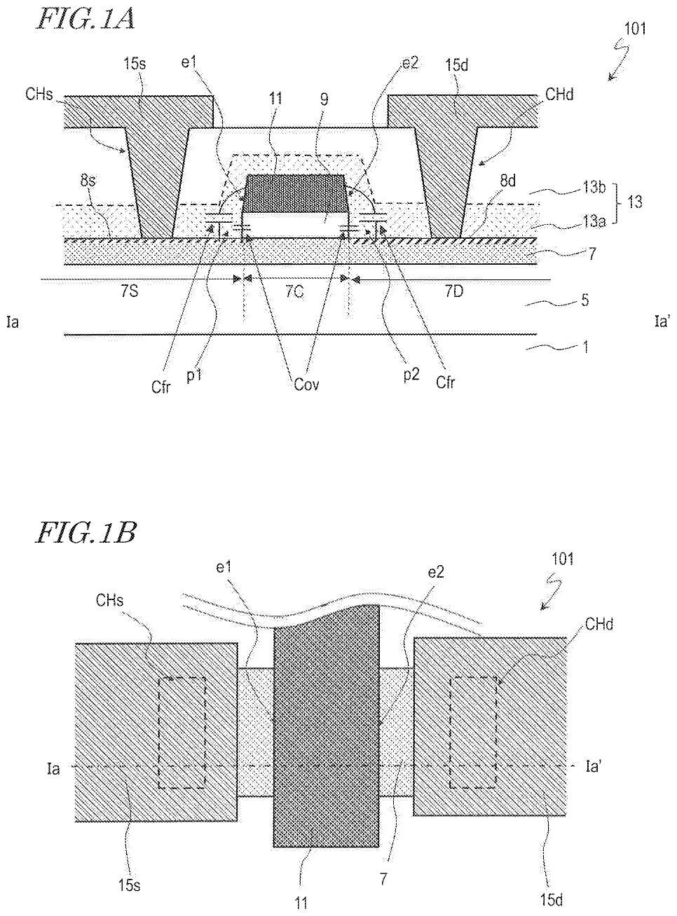

FIG. 1A and FIG. 1B are respectively a cross-sectional view and a plan view illustrating a TFT 101 of the present embodiment. FIG. 1A shows a cross section taken along line Ia-Ia′ of FIG. 1B.

The TFT 101 includes a substrate 1 such as glass substrate, an oxide semiconductor layer 7 supported by the substrate 1, a gate electrode 11, a gate insulating layer 9 interposed between the oxide semiconductor layer 7 and the gate electrode 11, and a source electrode 15s and a drain electrode 15d which are electrically coupled with the oxide semiconductor layer 7. In this example, the gate electrode 11 is provided on part of the oxide semiconductor layer 7 with the gate insulating layer 9 interposed therebetween (top gate configuration). Between the oxide semiconductor layer 7 and the substrate 1, a lower insulating layer 5 may be provided as an underlays.

When viewed in the normal direction of the substrate 1, the oxide semiconductor layer 7 includes a first region 7S, a second region 7D, and a region 7C located between the first region 7S and the second region 7D in which the channel of the TFT 101 is to be formed (channel region). The source electrode 15s is electrically coupled with the first region 7S. The drain electrode 15d is electrically coupled with the second region 7D.

At the surfaces of the first region 7S and the second region 7D of the oxide semiconductor layer 7, the oxide semiconductor layer 7 may have a first low-resistance reaction 8s and a second low-resistance region 8d, respectively, which have lower specific resistance than the surface of the channel region 7C. The source electrode 15s may be electrically coupled with the first low-resistance region 8s, and the drain electrode 15d may be electrically coupled with the second low-resistance region 8d.

When viewed in the normal direction of the substrate 1, the gate electrode 11 overlaps the channel region 7C but overlaps none of the first region 7S and the second region 7D. In this specification, when viewed in the normal direction of the substrate 1, a portion e1 of the lateral surfaces of the gate electrode 11 which is located on the first region 7S side and which overlaps the oxide semiconductor layer 7 is referred to as “first lateral surface portion”, and another portion e2 of the lateral surfaces of the gate electrode 11 which is located on the second region 7D side and which overlaps the oxide semiconductor layer 7 is referred to as “second lateral surface portion”.

The gate insulating layer 9 may be provided only between the oxide semiconductor layer 7 and the gate electrode 11. The gate insulating layer 9 and the gate electrode 11 may be, for example, patterned using the same mask.

An upper insulating layer 13 is provided on the oxide semiconductor layer 7, the gate insulating layer 9 and the gate electrode 11. The upper insulating layer 13 has a first opening CHs which reaches the first region 7S and a second opening CHd which reaches the second region 7D. The source electrode 15s is provided on the upper insulating layer 13 and in the first opening CHs. The source electrode 15s is electrically coupled with the first region 7S of the oxide semiconductor layer 7 (herein, the first low-resistance region 8s) in the first opening CHs. The drain electrode 15d is provided on the upper insulating layer 13 and in the second opening CHd. The drain electrode 15d is electrically coupled with the second region 7D of the oxide semiconductor layer 7 (herein, the second low-resistance region 8d) in the second opening CHd.

The upper insulating layer 13 includes a porous insulator layer 13a. In this specification, a region of the upper insulating layer 13 which can form capacitance (fringe capacitance) together with the first lateral surface portion e1 of the gate electrode 11 and the first region 7S of the oxide semiconductor layer 7 (herein, the first low-resistance region 8s) is referred to as “first fringe region”. Likewise, another region of the upper insulating layer 13 which can form fringe capacitance together with the second lateral surface portion e2 of the gate electrode 11 and the second region 7D of the oxide semiconductor layer 7 (herein, the second low-resistance region 8d) is referred to as “second fringe region”. The porous insulator layer 13a only need to be provided in at least part of the first fringe region and in at least part of the second fringe region. In other words, the porous insulator layer 13a includes a portion p1 which is present in the first fringe region (“first portion”) and a portion p2 which is present in the second fringe region (“second portion”).

FIG. 6 is a schematic cross-sectional view showing an example of the first and second fringe regions FR1, FR2. The first fringe region refers to, for example, a region FR1 of the upper insulating layer 13 which is located in the vicinity of the first lateral surface portion e1 of the gate electrode 11 when viewed in the normal direction of the substrate 1 and whose height from the upper surface of the oxide semiconductor layer 7 is smaller than the height hg of the upper surface of the gate electrode 11. The second fringe region refers to, for example, a region FR2 of the upper insulating layer 13 which is located in the vicinity of the second lateral surface portion e2 of the gate electrode 11 when viewed in the normal direction of the substrate 1 and whose height from the upper surface of the oxide semiconductor layer 7 is smaller than the height hg of the upper surface of the gate electrode 11. A region which is located “in the vicinity of the first lateral surface portion e1 (or the second lateral surface portion e2) of the gate electrode 11 when viewed in the normal direction of the substrate 1” means that, for example, in the plane of the substrate 1, the distance from the first lateral surface portion e1 or the second lateral surface portion e2 of the gate electrode 11 is not more than a predetermined length wf. The predetermined length wf may be equal to, for example, the thickness tg of the gate electrode 11. A region “whose height from the upper surface of the oxide semiconductor layer 7 is smaller than the height hg of the upper surface of the gate electrode 11” is, for example, a region located below a plane which includes the upper surface of the gate electrode 11 (on the substrate 1 side).

Examples of the porous insulator layer 13a include inorganic SOG (spin on glass) films such as porous silica films, and organic SOG films. The formation method of the porous insulator layer 13a is not limited to coating but may be any other method such as CVD. The porous insulator layer 13a may be, for example, a porous SiOC film or a porous SiOF film formed by CVD. The porous insulator layer 13a has a large number of minute pores inside the layer (relative permittivity: about 1) and therefore has a low dielectric constant. The relative permittivity of the porous insulator layer 13a may be, for example, no more than 3.0, preferably not more than 2.5. In this specification, the “relative permittivity” refers to a relative permittivity at the frequency of 1 MHz.

In the TFT 101 shown in FIG. 1A and FIG. 1B, the upper insulating layer 13 has a multilayer structure which includes a porous insulator layer 13a and a non-porous insulator layer 13b provided on the porous insulator layer 13a. The porous insulator layer 13a may be arranged so as to cover the oxide semiconductor layer 7, the gate insulating layer 9 and the gate electrode 11. The thickness of the porous insulator layer 13a may be set such that the porous insulator layer 13a can be provided across the entirety of the first and second fringe regions.

The merits achieved by providing the porous insulator layer 13a in the first and second fringe regions are described with reference to the drawings.

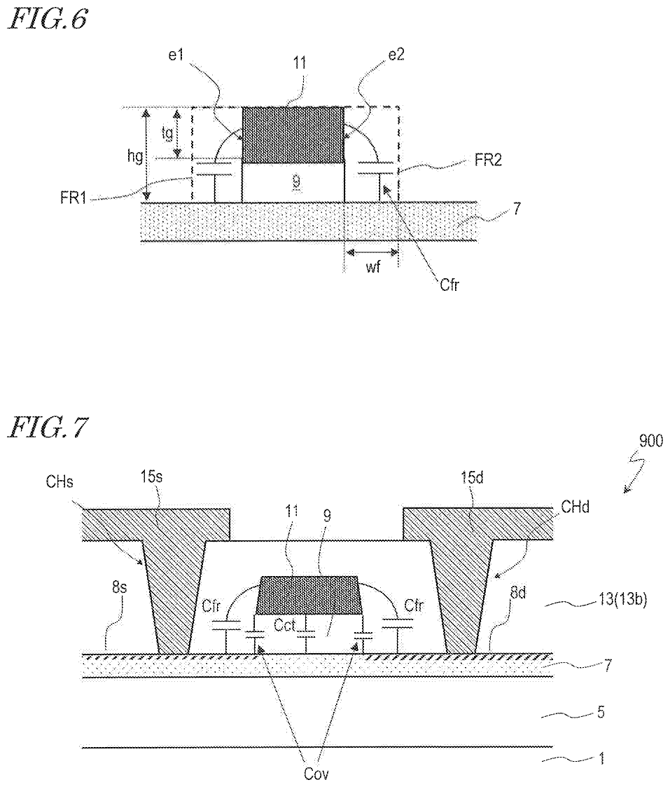

FIG. 7 is a schematic cross-sectional view of a TFT 900 of a reference example which has a top gate configuration. For the sake of simplicity, components which are equivalent to those of the TFT 101 shown in FIG. 1A are designated by the same reference numerals. The TFT 900 is different from the TFT 101 in that the upper insulating layer 13 does not include the porous insulator layer 13a and is formed by only the non-porous insulator layer 13b.

The parasitic capacitance Ctotal of the TFT 900 of the reference example includes the parasitic oxide film capacitance Cct of the gate electrode 11 and the oxide semiconductor layer 7, the capacitance Cov of portions in which the crate electrode 11 overlaps the first low-resistance region 8s and the second low-resistance region 8d (hereinafter, “overlap capacitance”), and the fringe capacitance Cfr. The fringe capacitance Cfr is the sum of the first capacitance which occurs between the first lateral surface portion e1 of the gate electrode 11 and the low-resistance region 8s and the second capacitance which occurs between the second lateral surface portion e2 of the gate electrode 11 and the low-resistance region 8d. The parasitic capacitance Ctotal is represented by the following formula (1).

Ctotal=Cct+2(Cov+Cfr)+Cov+Cfr (1)

Note that formula (1) additionally includes Cov+Cfr (mirror capacitance) in consideration of the mirror effect. Using the gate capacitance Cg (=Cct+2Cov), formula (1) can be transformed to the following formula (2).

Ctotal=Cg+3Cfr+Cov (2)

As seen from formula (2), particularly by decreasing the fringe capacitance Cfr, the parasitic capacitance Ctotal can be reduced more effectively (three times the decrease of the fringe capacitance Cfr).

When the gate electrode 11 and the gate insulating layer 9 are equal in shape, thickness, etc., the fringe capacitance Cfr increases as the relative permittivity ε of an insulative film (herein, the non-porous insulator layer 13b) located in the first and second fringe regions FR1, FR2 (see FIG. 6) increases. Usually, as the upper insulating layer 13 (the non-porous insulator layer 13b), a silicon oxide film (relative permittivity: for example, 3.9), a silicon nitride film (relative permittivity: for example, 7.5) such as Si₃N₄, or the like, is used.

In contrast, in the TFT 101 of the present embodiment, the porous insulator layer 13a that has small relative permittivity is provided in the first and second fringe regions. As a consequence of this arrangement, the relative permittivity ε of the insulative film that forms the fringe capacitance can be reduced, so that the fringe capacitance Cfr can be reduced. As seen from formula (2) shown above, as the fringe capacitance Cfr decreases, the total parasitic capacitance Ctotal is reduced by three times the decrease of the fringe capacitance Cfr. When, as an example, the area of the lateral surfaces of the gate electrode 11 and the thickness of the gate insulating layer 9 are equal, the fringe capacitance Cfr can be reduced by 46% by providing the porous insulator layer 13a (for example, porous silica (relative permittivity: 2.2)) in the first and second fringe regions as compared with a case where the non-porous insulator layer 13b (for example, silicon oxide (SiO₂) (relative permittivity: for example, 4.1)) is provided in the first and second fringe regions. As a result, the parasitic capacitance Ctotal can be reduced by three times the decrease of the fringe capacitance.

Thus, when the TFT 101 is used as a pixel circuit TFT of a display apparatus, occurrence or ghosting which is attributed to the parasitic capacitance can be suppressed. Further, the releasing time of the charge accumulated in the pixel circuit TFT can be shortened, and therefore, the refresh rate, the qrayscale performance, etc., can be improved. Furthermore, when the TFT 101 is used as a peripheral circuit TFT, various merits can be achieved. For example, the power consumption can be reduced, and the operation speed of the peripheral circuits can be improved.

As previously described, the porous insulator layer 13a includes the first portion p1 which is present in the first fringe region FR1 shown in FIG. 6 and the second portion p2 which is present in the second fringe region FR2 shown in FIG. 6. The porous insulator layer 13a only need to be provided in at least part of the respective fringe regions. Alternatively, the porous insulator layer 13a may be provided so as to fill the entirety of the first and second fringe regions FR1, FR2. In this case, the fringe capacitance can be reduced more effectively.

As shown in FIG. 1A and FIG. 1B, the upper insulating layer 13 may include the porous insulator layer 13a and the non-porous insulator layer 13b provided on the porous insulator layer 13a. In this case, the fringe capacitance can be reduced by the porous insulator layer 13a while the mechanical strength and the barrier performance of the upper insulating layer 13 are secured by the non-porous insulator layer 13b.

In each fringe region, the porous insulator layer 13a may be provided so as to be in contact with the lateral surfaces of the gate electrode 11. That is, the first portion p1 of the porous insulator layer 13a may be in contact with the first lateral surface portion e1 of the gate electrode 11, and the second portion p2 of the porous insulator layer 13a may be in contact with the second lateral surface portion e2 of the gate electrode 11. Alternatively, each of the first portion p1 and the second portion p2 of the porous insulator layer 13a may be arranged so as to be in contact with a lateral surface of the gate insulating layer 9. As illustrated in the drawings, the first portion p1 and the second portion p2 of the porous insulator layer 13a may be in contact with the first and second lateral surface portions e1, e2, respectively, of the gate electrode 11 and be in contact with the lateral surfaces of the gate insulating layer 9.

As illustrated in the drawings, the first portion p1 of the porous insulator layer 13a may be arranged so as to cover the entirety of the first lateral surface portion e1 of the gate electrode 11, and the second portion p2 of the porous insulator layer 13a may be arranged so as to cover the entirety of the second lateral surface portion e2 of the gate electrode 11. In this case, the fringe capacitance can be reduced more effectively. The first portion p1 of the porous insulator layer 13a may be in contact with the entirety of the first lateral surface portion e1, and the second portion p2 may be in contact with the entirety of the second lateral surface portion e2.

The first portion p1 of the porous insulator layer 13a may be in contact with at least part of the first region 7S (the first low-resistance region 8s), and the second portion p2 of the porous insulator layer 13a may be in contact with at least part of the second region 7D (the second low-resistance region 8d). In this case, the fringe capacitance can be reduced more effectively. From this viewpoint, a more preferred porous insulative material is a nonorganic material which has high dielectric strength (for example, silica material).

The pores of the porous insulator layer 13a may be open pores or may be closed pores. The porosity of the porous insulator layer 13a (the ratio of the volume of the pores to the total volume of the porous insulator layer 13a) may be, for example, not less than 3% and not more than 30%. If it is not less than 3%, the dielectric constant of the porous insulator layer 13a can be further reduced. If it is not more than 30%, the porous insulator layer 13a can have a higher mechanical strength. The average pore diameter of the porous insulator layer 13a is not particularly limited but may be not less than 2 nm and not more than 20 nm. When the major constituent of the porous insulator layer 13a is a silicon oxide, the density of the porous insulator layer 13a may be not less than 0.05 g/cm³ and not more than 0.3 g/cm³.

The thickness of the porous insulator layer 13a may be, for example, not less than 100 nm, or equal to or greater than the thickness of the gate electrode 11. In this case, the proportion of the porous insulator layer 13a in each fringe region is high, so that the fringe capacitance can be reduced more effectively. Meanwhile, the thickness of the porous insulator layer 13a may be, for example, not more than 500 nm, or not more than ⅓ of the thickness of the entirety of the upper insulating layer 13. In this case, occurrence of cracks in the porous insulator layer 13a can be suppressed.

Meanwhile, the non-porous insulator layer 13b is, for example, an insulating layer which does not have a pore of 100 nm or greater in size or an insulating layer whose porosity is less than 3%. The non-porous insulator layer 13b may be, for example, a silicon nitride layer or a silicon oxide layer formed by CVD or a multilayer film thereof. The thickness of the non-porous insulator layer 13b is not particularly limited but may be greater than the thickness of the porous insulator layer 13a. In this case, the mechanical strength of the upper insulating layer 13 can be more surely secured. The thickness of the non-porous insulator layer 13b may be, for example, not less than 500 nm and not more than 1000 nm, or not less than ½ and not more than ⅘ of the thickness of the entirety of the upper insulating layer 13.

In the TFT 101, the gate electrode 11, the source electrode 15s and the drain electrode 15d are preferably arranged such that the gate electrode 11 overlaps none of the source electrode 15s and the drain electrode 15d when viewed in the normal direction of the substrate 1. It is also preferred that the overlap length of the gate electrode 11 with the source electrode 15s and the drain electrode 15d is suppressed to a small length. Thereby, the parasitic capacitance between. the gate electrode 11 and the source electrode 15s and the drain electrode 15d can be reduced.

Although not shown, a light shielding layer may be further provided the substrate 1 side of the oxide semiconductor layer 7 (channel region 7C). Note that, however, in the case of a display apparatus which does not need a backlight, such as micro LED display apparatus, the light shielding layer may not be provided. Alternatively, another gate electrode (lower gate electrode) may be provided on the substrate 1 side of the oxide semiconductor layer 7 with another gate insulating layer interposed therebetween (double gate structure). The lower gate electrode may be connected with the gate electrode 11 or may be connected with a fixed potential. From the viewpoint of reducing the parasitic capacitance, it is preferred that the light shielding layer or the lower gate electrode is not provided.

The oxide semiconductor contained in the oxide semiconductor layer 7 is not particularly limited. Examples of the oxide semiconductor which can be used herein include binary oxides such as In—Zn based oxides and In—Ga based oxides, ternary oxides such as In—Ga—Zn based oxides and In—Sn—Zn based oxides, and quaternary metal oxides such as In—Sn—Ga—Zn based oxides. The oxide semiconductor may be amorphous or may be crystalline. The crystalline oxide semiconductor may be, for example, a polycrystalline oxide semiconductor, a microcrystalline oxide semiconductor, or a crystalline oxide semiconductor in which the c-axis is oriented generally perpendicular to the layer surface. The materials, compositions, structures and film formation methods of the amorphous or crystalline oxide semiconductor are disclosed in, for example, Japanese Patent No. 6275294. The disclosure of Japanese Patent No. 6275294 is incorporated herein by reference in its entirety.

<Manufacturing Method of TFT 101>

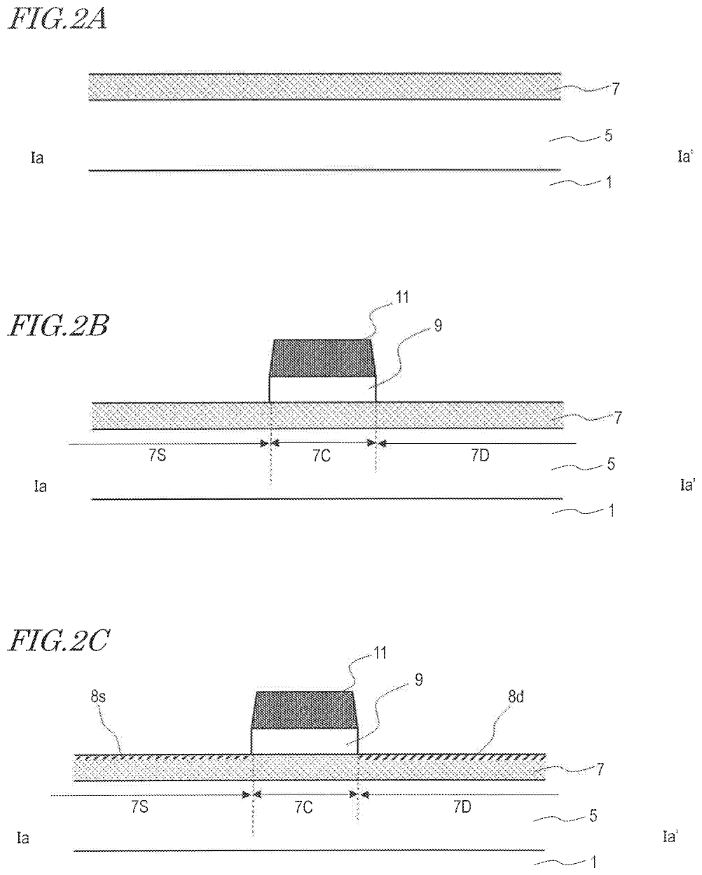

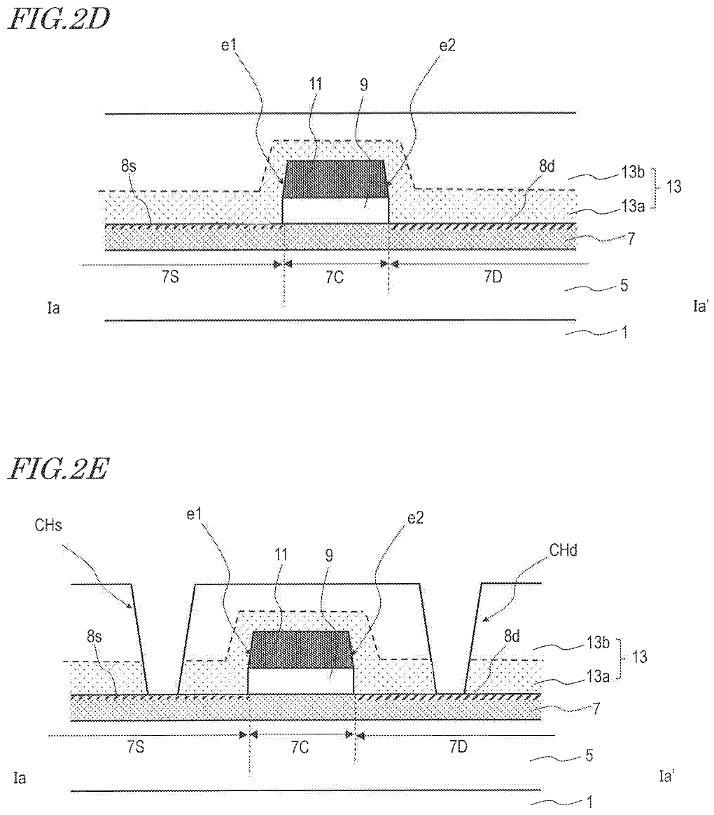

An example of the manufacturing method of the TFT 101 is described with reference to FIG. 2A to FIG. 2E.

Step 1: Forming Lower Insulating Layer

First, as shown in FIG. 2A, a lower insulating layer 5 is formed on the substrate 1. As the substrate 1, for example, a substrate which has an insulative surface, such as glass substrate, silicon substrate, thermostable plastic substrate (resin substrate), etc., can be used.

As the lower insulating layer 5, a silicon oxide (SiO₂) layer, a silicon nitride (SiNx) layer, a silicon oxynitride (SiOxNy; x>y) layer, a silicon nitroxide (SiNxOy; x>y) layer, or the like, can be appropriately used. The lower insulating layer 5 may have a multilayer structure. Herein, as the lower insulating layer 5, for example, a multilayer film is formed by CVD which includes a silicon nitride (SiNx) layer as the lower layer and a silicon oxide (SiO₂) layer as the upper layer. When an oxide film, such as silicon oxide film, is used as the lower insulating layer 5 (if the lower insulating layer 5 has a multilayer structure, as the uppermost layer of the multilayer structure), oxidation deficiencies in the channel region 7C of the oxide semiconductor layer 7 that is formed in a subsequent step can be reduced by the oxide film and, therefore, decrease in resistance of the channel region 7C can be suppressed. The thickness of the lower insulating layer 5 is not particularly limited but may be, for example, not less than 300 nm and not more than 600 nm.

Step 2: Forming Oxide Semiconductor Layer

Then, as shown in FIG. 2A, an oxide semiconductor layer 7 is formed on the lower insulating layer 5.

Herein, firstly, an oxide semiconductor film (for example, an In—Ga—Zn—O based semiconductor film) is formed on the lower insulating layer 5. The oxide semiconductor film is formed by, for example, sputtering. As the sputtering gas (atmosphere), a mixture gas of an inert gas such as argon gas and an oxidizing gas such as O₂, CO₂, O₃, H₂O, N₂O, or the like, can be used. The formation conditions, such as the sputtering target used, she mixture ratio of the sputtering gas (the proportion of the oxygen gas to the inert gas), etc., can be appropriately selected according to the composition (or composition ratio) of the oxide semiconductor film to be formed.

Thereafter, a heat treatment on the oxide semiconductor film (first heat treatment) may be performed. Herein, the heat treatment is carried out in the environmental atmosphere at a temperature equal to or higher than 300° C. and equal to or lower than 500° C. The duration of the first heat treatment is, for example, not less than 30 minutes and not more than 2 hours. By this heat treatment, the oxygen deficiencies in the channel region 7C can be reduced, so that desired TFT characteristics can be achieved. The first heat treatment may be carried out, after formation of an applied film which is to be the porous insulator layer 13a, so as to serve as a heat treatment on the applied film (second heat treatment).

Then, the oxide semiconductor film is patterned, resulting in an oxide semiconductor layer. The patterning of the oxide semiconductor film may be realized by, for example, wet etching. The thickness of the oxide semiconductor layer 7 may be, for example, not less than 100 nm and not more than 200 nm.

Step 3: Forming Gate Insulating Layer and Gate Electrode

Then, as shown in FIG. 2B, a gate insulating layer 9 and a gate electrode 11 are formed on part of the oxide semiconductor layer 7.

First, an insulative film, which is to be the gate insulating layer, and an electrically-conductive gate film, which is to be the gate electrode, are formed in this order so as to cover the oxide semiconductor layer 7. The thickness of the insulative film is not particularly limited but may be not less than 100 nm and not more than 500 nm, for example not less than 300 nm and not more than 400 nm. The thickness of the electrically-conductive gate film is not particularly limited but may be, for example, not less than 100 nm and not more than 500 nm.

The insulative film which is to be the gate insulating layer can be formed by, for example, CVD. As the insulative film, a silicon oxide (SiO₂) film, a silicon nitride (SiNx) film, a silicon oxynitride (SiOxNy; x>y) film, a silicon nitroxide (SiNyOx; y>x) film, or a multilayer film thereof can be appropriately used. When an oxide film such as silicon oxide film is used as the insulative film (if a multilayer film is used, as the lowermost film of the multilayer film), oxidation deficiencies in the channel region 7C of the oxide semiconductor layer 7 can be reduced and, therefore, decrease an resistance of the channel region 7C can be suppressed.

The electrically-conductive gate film can be formed by, for example, sputtering. As the material of the electrically-conductive gate film, for example, a single metal such as molybdenum (Mo), tungsten (W), copper (Cu), chromium (Cr), tantalum (Ta), aluminum (Al), titanium (Ti), etc., a material prepared by adding nitrogen, oxygen, or another metal to the single metal, or a transparent electrically-conductive material such as indium tin oxide (ITO) can be used.

Subsequently, a first resist mask (not shown) is formed on part of the electrically-conductive gate film. Thereafter, patterning of the electrically-conductive gate film is performed using the first resist mask, whereby a gate electrode 11 is formed. The patterning of the electrically-conductive gate film can be realized by wet etching or dry etching.

Then, patterning of the insulative film is carried out using the first resist mask. Alternatively, after the first resist mask is removed, patterning of the insulative film may be carried out using the patterned gate electrode 11 as a mask. The patterning of the insulative film may be realized by, for example, dry etching. As a consequence of this patterning, the gate insulating layer 9 of the TFT 101 is formed, and the surfaces of parts of the oxide semiconductor layer 7 which are to be the first region 7S and the second region 7D are exposed.

In this step, patterning of the insulative film and patterning of the electrically-conductive gate film are carried out using the same mask (first resist mask), Therefore, the lateral surfaces of the gate insulating layer 9 and the lateral surfaces of the gate electrode 11 can be aligned in the thickness direction. That is, when viewed in the normal direction of the substrate 1, the periphery of the gate insulating layer 9 and the periphery of the gate electrode 11 can be in accordance with each other.

In the above-described dry etching, in some cases, a surface portion of the oxide semiconductor layer 7 (for example, a surface portion of he upper oxide semiconductor layer 72) can be etched away together with the insulative film.

### Step 4: Resistance Reduction Treatment

Then, as shown in FIG. 2C, a resistance reduction treatment is performed such that a portion of the oxide semiconductor layer 7 which does not overlap the gate electrode 11 when viewed in the normal direction of the substrate 1 has lower specific resistance than another portion which overlaps the gate electrode 11, whereby low-resistance regions 8s, 8d are formed. Herein, a resistance reduction treatment is performed on the exposed surfaces of the oxide semiconductor layer 7 (the surfaces of the first region 7S and the second region 7D) using the gate electrode 11 as a mask. The resistance reduction treatment may be, for example, a plasma treatment. Examples of the plasma treatment include argon plasma treatment, ammonium plasma treatment, and hydrogen plasma treatment. Alternatively, low-resistance regions 8s, 8d may be formed at the surfaces of the first region 7S and the second region 7D by adding nitrogen, phosphorus, or the like, to the oxide semiconductor layer 7 by ion implantation using the gate electrode 11 as a mask.

Alternatively, by using an insulative film which can deoxidise the oxide semiconductor such as a nitride film (e.g., silicon nitride film) as the upper insulating layer 13, the resistance of regions of the oxide semiconductor layer 7 which are in contact with the nitride film (the surfaces of the first region 7S and the second region 7D) can be reduced to a level lower than the resistance of a region of the oxide semiconductor layer 7 which is in contact with the oxide film (the surface of the channel region 7C).

### Step 5: Forming Upper Insulating Layer

Then, as shown in FIG. 2D, an upper insulating layer 13 is formed so as to cover the gate electrode 11, the gate insulating layer 9 and the oxide semiconductor layer 7. In this example, as the upper insulating layer 13, a multilayer film is formed which includes a porous insulator layer 13a and a non-porous insulator layer 13b. The thickness of the entirety of the upper insulating layer 13 is not particularly limited but may be, for example, not less than 1000 nm and not more than 1500 nm.

Specifically, first, a SOG solution is applied so as to cover the gate electrode 11, the gate insulating layer 9 and the oxide semiconductor layer 7. The SOG solution used herein is a silica (siloxane) solution for formation of insulative films, HSG-225 (Hitachi Chemical Company, Ltd.). Then, drying and a heat treatment (second heat treatment) are performed on the resultant applied film (SOC film). The second heat treatment may be carried out, for example, at a temperature equal to or higher than 400° C. and equal to or lower than 450° C. for the duration of not less than 0.5 hour and not more than 5 hours. As a consequence, a porous insulator layer 13a (for example, relative permittivity: 2.3, elastic modulus: 12 GPa, hardness: 1.3 GPa, porosity 20%) is formed. The thickness of the porous insulator layer 13a may be, for example, 500 nm. The second heat treatment may be realized by the first heat treatment that is performed on the oxide semiconductor layer 7.

Herein, the porous insulator layer 13a is formed so as to be in contact with the exposed surface of the oxide semiconductor layer 7 (the low-resistance regions 8s, 8d of the first region 7S and the second region 7D). The porous insulator layer 13a may be in contact with the surfaces of the gate electrode 11 and the gate insulating layer 9.

Then, as the non-porous insulator layer 13b, an inorganic insulating layer such as a silicon oxide layer, a silicon nitride layer, a silicon oxynitride layer, a silicon nitroxide layer, or the like, can be formed on the porous insulator layer 13a such that the inorganic insulating layer has a single layer structure or a multilayer structure. The non-porous insulator layer 13b can be formed by, for example, CVD. The thickness of the non-porous insulator layer 13b may be, for example, 500 nm.

Thereafter, as shown in FIG. 2E, a first opening CHs and a second opening CHd are formed in the upper insulating layer 13 by, for example, dry etching such that the first opening CHs reaches the surface of the first region 7S (the first low-resistance region 8s) and the second opening CHd reaches the surface of the second region 7D (the second low-resistance region 8d).

Step 6: Forming Source and Drain Electrodes

Then, an electrically-conductive source film is formed on the upper insulating layer 13 and in the first opening CHs and the second opening CHd, and the formed electrically-conductive source film is patterned. Thereby, a source electrode 15s and a drain electrode 15d are formed from the electrically-conductive source film. In this way, the TFT 101 shown in FIG. 1A is manufactured.

The material of the electrically-conductive source film can be the same as the material of the above-described electrically-conductive gate film. The thickness of the electrically-conductive source film is not particularly limited but may be, for example, not less than 400 nm and not more than 800 nm. The patterning of the electrically-conductive source film can be realized by dry etching or wet etching.

<Variation 1>

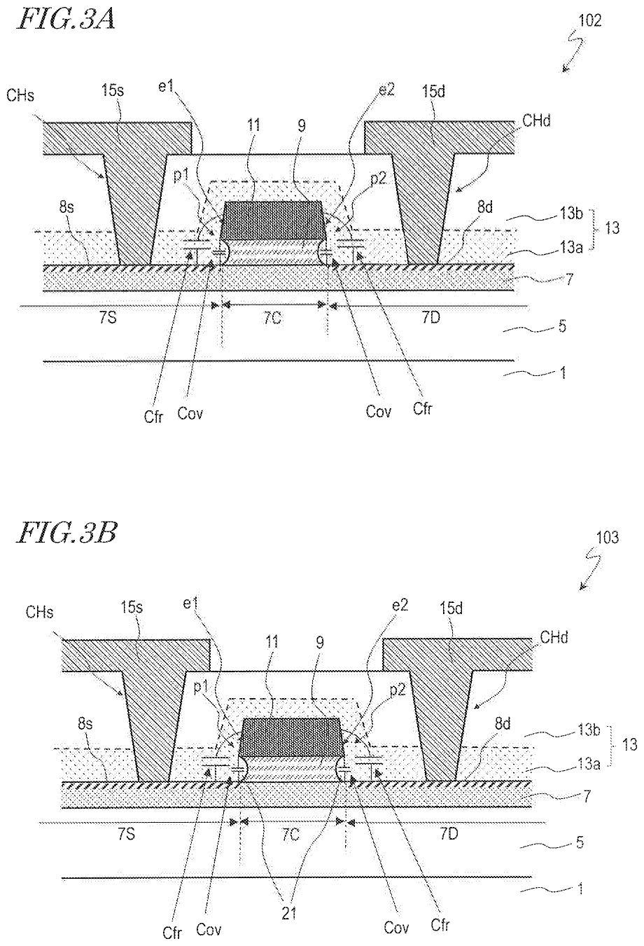

FIG. 3A is a cross-sectional view illustrating another TFT 102 of the present embodiment.

In the TFT 102, the lateral surfaces of the gate insulating layer 9 are more internal than the lateral surfaces of the gate electrode 11, and the porous insulator layer 13a is also provided between the peripheral portion of the gate electrode 11 and the channel region 7C of the oxide semiconductor layer 7. The other features may be the same as those of the TFT 101.

The relative permittivity of the porous insulator layer 13a is smaller than the relative permittivity of the gate insulating layer 9. The porous insulator layer 13a may be, for example, a silica porous insulative film (relative permittivity: 2.3) or may be another porous insulative film that has previously been described.

The gate insulating layer 9 contains, for example, a silicon oxide (relative permittivity: for example, 3.9). The gate insulating layer 9 may be a single layer of a silicon oxide or may have a multilayer structure which includes a silicon oxide layer. For example, the gate insulating layer 9 may be a multilayer film which includes a silicon oxide layer arranged so as to be in contact with the oxide semiconductor layer 7 and a silicon nitride layer (relative permittivity: for example, 7.5) provided on the silicon oxide layer.

In the TFT 102, the porous insulator layer 13a is provided not only in the first and second fringe regions FR1, FR2 (see FIG. 6) but also under the peripheral portion of the gate electrode 11, and therefore, not only the fringe capacitance Cfr but also overlap capacitance Cov can be reduced. Thus, the parasitic capacitance Ctotal can be reduced more effectively.

The TFT 102 can be manufactured by the same method as that of the TFT 101. However, it is different from the manufacturing method of the TFT 101 in that side etching is performed on the gate insulating layer 9 such that the lateral surfaces of the gate insulating layer 9 are more internal than the lateral surfaces of the gate electrode 11.

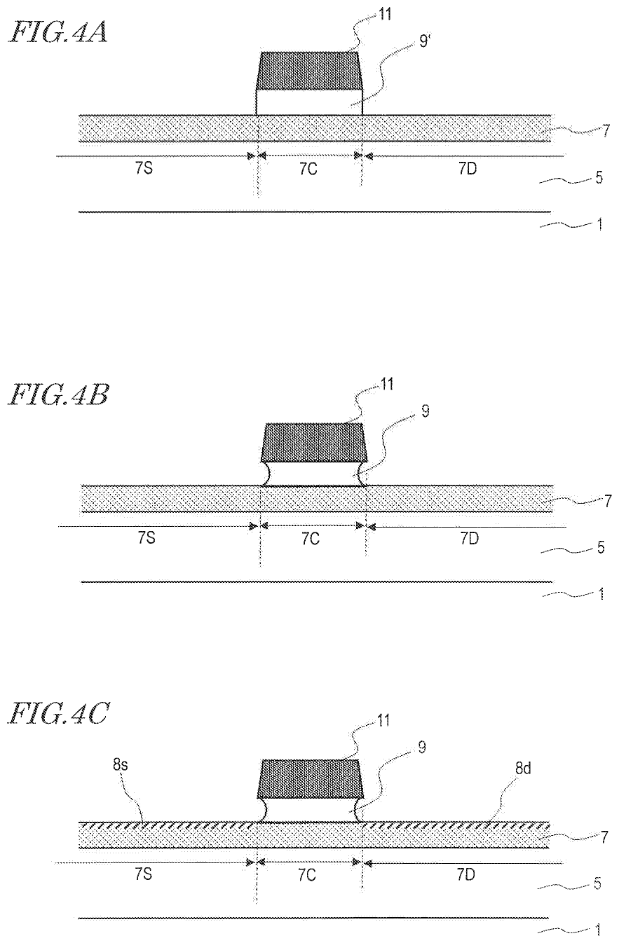

For example, in STEP 3, as shown in FIG. 4A, patterning of the insulative film which is to be the gate insulating layer 9 is performed by anisotropic etching using the first resist mask or using the pate electrode 11 as a mask. Then, as shown in FIG. 4B, etching (side etching) is performed on the lateral surfaces of the patterned insulative film 9′ (referred to as “gate insulating layer precursor”). When the gate insulating layer precursor 9′ is a SiO₂ film, the side etching is realized by, for example, a hydrofluoric acid treatment, whereby the gate insulating layer 9 is formed.

Instead of using the above-described method, the gate insulating layer 9 which has the shape shown in FIG. 4B may be formed by performing isotropic etching of the insulative film using the first resist mask or using the gate electrode 11 as a mask.

Then, as shown in FIG. 4C, the resistance reduction treatment of STEP 4 is performed. Then, although not shown, in STEP 5, the upper insulating layer 13 is formed so as to fill the gap between the gate electrode 11 and the oxide semiconductor layer 7. The upper insulating layer 13 may be in contact with. the lateral surfaces of the crate insulating layer 9. Thereafter, the source electrode 15s and the drain electrode 15d are formed, whereby the TFT 102 is manufactured.

FIG. 3B is a cross-sectional view illustrating still another TFT 103 of the present embodiment.

In the TFT 103, the lateral surfaces of the gate insulating layer 9 are more internal than the lateral surfaces of the gate electrode 11. There are air gaps (i.e. empty spaces) 21 provided between the peripheral portion of the gate electrode 11 and the channel region 7C of the oxide semiconductor layer 7 and between the lateral surfaces of the gate insulating layer 9 and the upper insulating layer 13. The relative permittivity of the air caps 21 is about 1 and is smaller than relative permittivity of the non-porous insulator layer 13b and the gate insulating layer 9.

In the TFT 103, the porous insulator layer 13a is provided in the first and second fringe regions FR1, FR2 (see FIG. 6), and the air gaps 21 are provided under the peripheral portion of the gate electrode 11. Therefore, likewise as in the TFT 102, not only the fringe capacitance Cfr but also the overlap capacitance Cov can be reduced, and therefore, the parasitic capacitance Ctotal can be reduced more effectively.

The TFT 103 can be manufactured by performing side etching of the rate insulating layer 9 as is the TFT 102. Note that, however, in STEP 5, the upper insulating layer 13 is formed such that the air gaps 21 (not including holes inside the porous insulator) occur at least partially between the lateral surfaces of the gate insulating layer 9 and the upper insulating layer 13. Thereafter, a source electrode 15s and a drain electrode 15d are formed, whereby the TFT 103 is manufactured.

<Variation 2>

The porous insulator layer 13a only need to be at least partially provided in each of the first and second fringe regions FR1, FR2 (see FIG. 6) and does not need to be the lowermost layer in the upper insulating layer 13.

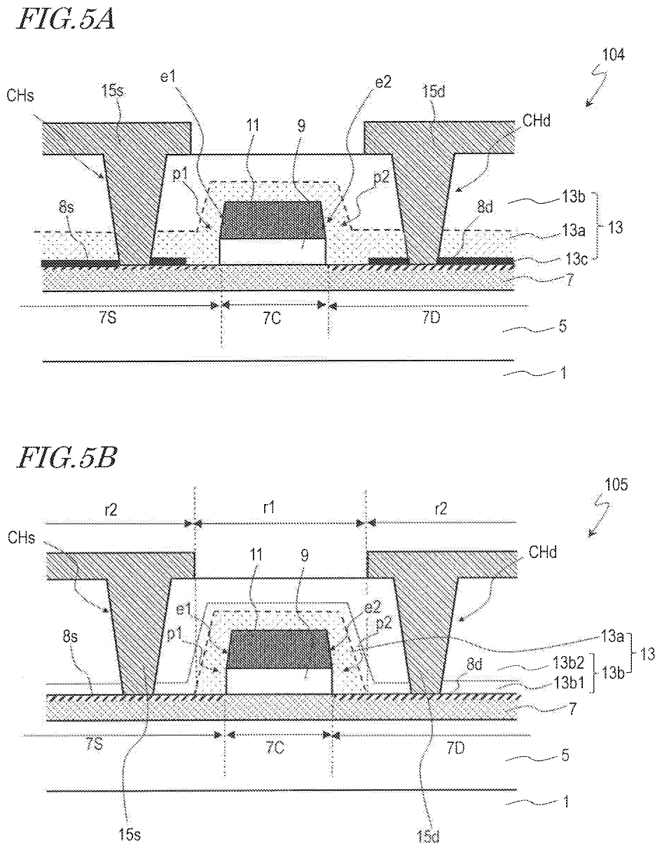

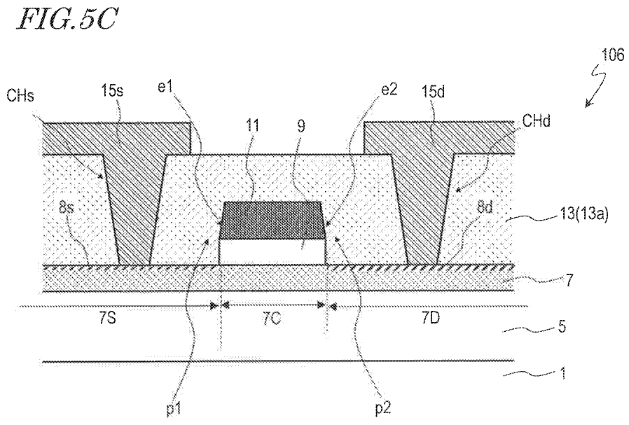

FIG. 5A to FIG. 5C are cross-sectional views respectively illustrating other TFTs 104, 105, 106 of the present embodiment.

For example, as shown in FIG. 5A, a deoxidizing insulative film 13c which can deoxidize the oxide semiconductor of the oxide semiconductor layer 7 (e.g., SiNx film) is formed as the lowermost layer in the upper insulating layer 13, and a porous insulator layer 13a and a non-porous insulator layer 13b are formed in this order on the insulative film 13c. By providing the insulative film 13c, the specific resistance of the low-resistance regions 8s, 8d can be suppressed to a lower level. Note that, however, from the viewpoint of reducing the parasitic capacitance of the TFT 104, parts of the insulative film 13c lying in the first and second fringe regions FR1, FR2 (see FIG. 6) may be removed.

Alternatively, as shown in FIG. 5B, the porous insulator layer 13a may be patterned. The porous insulator layer 13a may be, for example, an insulator layer in the shape of an island. The upper insulating layer 13 includes a portion r1 which includes the first and second fringe regions FR1, FR2 (“first insulating portion”) and a portion r2 which lies outside the first insulating portion r1 (“second insulating portion”) when viewed in the normal direction of the substrate 1. The first insulating portion r1 has a multilayer structure which includes the porous insulator layer 13a and the non-porous insulator layer 13b provided on the porous insulator layer 13a. The second insulating portion r2 includes the non-porous insulator layer 13b but does not include the porous insulator layer 13a. As illustrated in the drawings, a first opening CHs and a second opening CHd may be provided in the second insulating portion r2 of the upper insulating layer 13. In such a configuration, the porous insulator is not exposed at the lateral walls of the first opening CHs and the second opening CHd, and therefore, there is a merit in that diffusion of the metal of the electrodes into the upper insulating layer 13 can be suppressed.

When a deoxidizing insulative film which can deoxidize the oxide semiconductor of the oxide semiconductor layer 7 (e.g., SiNx film) is used as the non-porous insulator layer 13b (if the non-porous insulator layer 13b has a multilayer structure, as the lowermost layer), the specific resistance of part of the low-resistance regions 8s, 8d which is in contact with the second insulating portion r2 can be suppressed to a lower level. For example, the non-porous insulator layer 13b may be a multilayer film consisting of a deoxidizing insulative film 13b1 (e.g., SiNx film), which is in contact with the low-resistance regions 8s, 8d, and an oxidizing insulative film 13b2 (e.g., SiO₂ film).

Alternatively, as illustrated in FIG. 5C, the upper insulating layer 13 may have a single layer structure of the porous insulator layer 13a.

The TFT 104, the TFT 105 and the TFT 106 can be manufactured by the same method as that of the TFT 101 previously described with reference to FIG. 2A to FIG. 2E.

Also in the TFT 104, the TFT 105 and the TFT 106, the gate insulating layer 9 is side-etched, and the porous insulator layer 13a or the air gaps 21 may be provided under the peripheral portion of the gate electrode 11 (see FIG. 3A, FIG. 3B).

<Display Apparatus>

The thin film transistors of the present embodiment are applicable to, for example, circuit boards such as active matrix substrates, various display apparatuses such as liquid crystal display apparatuses, organic EL display apparatuses, and micro LED display apparatuses, image sensors, electronic devices, etc.

Hereinafter, an active matrix substrate and a display apparatus which include thin film transistors of the present embodiment are described.

The active matrix substrate has a display region which includes a plurality of pixels and pixel circuits which are arranged so as to correspond to respective ones of the plurality of pixels. Each of the pixel circuits includes at least one than film transistor (pixel circuit TFT) as a circuit element. In a region of the active matrix substrate exclusive of the display region (peripheral region), peripheral circuits such as driving circuits are monolithically (integrally) provided in some cases. The peripheral circuit includes at least one thin film transistor (peripheral circuit TFT) as a circuit element. The thin film transistors of the present embodiment can be used as a pixel circuit TFT and/or a peripheral circuit TFT. Such an active matrix substrate can be used not only in a voltage-driven display apparatus, such as liquid crystal display apparatuses, but also in a current-driven display apparatus.

The thin film transistors of the present embodiment are suitably applicable to, particularly, current-driven display apparatuses. In a current-driven display apparatus such as organic EL display apparatus, micro LED display apparatuses, or the like, a plurality of current-driven light emitting devices (organic EL device, LED device, etc.) are arranged so as to correspond to respective pixels. Each pixel circuit. (also referred to as “pixel driving circuit”) drives a corresponding one of the light emitting devices. In the thin film transistors of the present embodiment, the parasitic capacitance can be reduced, and therefore, occurrence of ghosting can be suppressed, and higher display quality can be achieved. Configurations of the pixel driving circuit are disclosed in, for example, WO 2016/035413 and WO 2004/107303. The disclosures of these documents are incorporated herein by reference in their entireties.

This application is based on U.S. Provisional Patent Applications No. 62/859,478 filed on Jun. 10, 2019, the entire contents of which are hereby incorporated by reference.

What is claimed is:

1. A thin film transistor comprising:
a substrate;
an oxide semiconductor layer supported by the substrate, the oxide semiconductor layer including a first region, a second region, and a channel region located between the first region and the second region;
a gate electrode provided on the channel region of the oxide semiconductor layer with a gate insulating layer interposed therebetween;
a source electrode electrically coupled with the first region of the oxide semiconductor layer;
a drain electrode electrically coupled with the second region of the oxide semiconductor layer; and
an upper insulating layer covering the oxide semiconductor layer, the gate insulating layer and the gate electrode, wherein
when viewed in a normal direction of the substrate, the gate electrode overlaps the channel region of the oxide semiconductor layer but overlaps none of the first region and the second region,
when viewed in the normal direction of the substrate, a lateral surface of the gate electrode includes a first lateral surface portion located on the first region side and overlapping the oxide semiconductor layer and a second lateral surface portion located on the second region side and overlapping the oxide semiconductor layer,
the upper insulating layer includes
a first fringe region which is located in a vicinity of the first lateral surface portion of the gate electrode when viewed in the normal direction of the substrate and whose height from an upper surface of the oxide semiconductor layer is smaller than a height of an upper surface of the gate electrode, and
a second fringe region which is located in a vicinity of the second lateral surface portion of the gate electrode when viewed in the normal direction of the substrate and whose height from the upper surface of the oxide semiconductor layer is smaller than the height of the upper surface of the gate electrode,
the upper insulating layer includes a porous insulator layer, the porous insulator layer including a first portion located in the first fringe region and a second portion located in the second fringe region, and
the first portion of the porous insulator layer is in contact with at least part of the first region of the oxide semiconductor layer, and the second portion of the porous insulator layer is in contact with at least part of the second region of the oxide semiconductor layer.

2. The thin film transistor of claim 1, wherein the gate insulating layer includes a silicon oxide layer.

3. The thin film transistor of claim 1, wherein a relative permittivity at the frequency of 1 MHz of the porous insulator layer is not more than 3.0.

4. The thin film transistor of claim 1, wherein the first portion of the porous insulator layer is in contact with the first lateral surface portion of the gate electrode, and the second portion of the porous insulator layer is in contact with the second lateral surface portion of the gate electrode.

5. The thin film transistor of claim 1 wherein, when viewed in the normal direction of the substrate, a lateral surface of the gate insulating layer and the lateral surface of the gate electrode are aligned.

6. The thin film transistor of claim 5, wherein the porous insulator layer is in contact with the lateral surface of the gate insulating layer.

7. The thin film transistor of claim 1 wherein, when viewed in the normal direction of the substrate, a lateral surface of the gate insulating layer is more internal than the lateral surface of the gate electrode.

8. The thin film transistor of claim 7, wherein at least part of the porous insulator layer is located between the gate electrode and the channel region so as to be in contact with the lateral surface of the gate insulating layer.

9. The thin film transistor of claim 7, wherein there is an air gap provided between the gate electrode and the channel region and between the lateral surface of the gate insulating layer and the upper insulating layer.

10. The thin film transistor of claim 1, wherein the upper insulating layer includes a non-porous insulator layer provided on the porous insulator layer.

11. The thin film transistor of claim 10, wherein
the upper insulating layer includes a first insulating portion which includes the first fringe region and the second fringe region and a second insulating portion which lies outside the first insulating portion when viewed in the normal direction of the substrate,
the first insulating portion includes the porous insulator layer and the non-porous insulator layer, and the second insulating portion includes the non-porous insulator layer but does not include the porous insulator layer, and
the second insulating portion has a first opening for connecting the source electrode with the first region and a second opening for connecting the drain electrode with the second region.

12. The thin film transistor of claim 1, wherein a thickness of the porous insulator layer is not less than a thickness of the gate electrode.

13. The thin film transistor of claim 1, wherein the porous insulator layer is formed by an organic SOG film or an inorganic SOG film.

14. The thin film transistor of claim 1, wherein
the first region of the oxide semiconductor layer has at its surface a first low-resistance region whose specific resistance is smaller than that of the channel region, and the second region of the oxide semiconductor layer has at its surface a second low-resistance region whose specific resistance is smaller than that of the channel region, and
the first portion of the porous insulator layer is in contact with at least part of the first low-resistance region, and the second portion of the porous insulator layer is in contact with at least part of the second low-resistance region.

15. A display apparatus comprising:
the thin film transistor as set forth in claim 1;
a display region which has a plurality of pixels; and
a pixel circuit arranged so as to correspond to respective ones of the plurality of pixels,
wherein the pixel circuit includes the thin film transistor

16. The display apparatus of claim 15, further comprising current-driven light emitting device arranged so as to correspond to respective ones of the plurality of pixels, wherein the pixel circuit drives the light emitting device.

17. A manufacturing method of a thin film transistor supported by a substrate, the method comprising steps of:
(A) forming an oxide semiconductor layer on the substrate;
(B) forming a gate insulating layer and a gate electrode in this order on part of the oxide semiconductor layer; and
(C) forming an upper insulating layer so as to cover the oxide semiconductor layer, the gate insulating layer and the gate electrode, the upper insulating layer including a porous insulator layer,
wherein the upper insulating layer includes
a first fringe region which is located in a vicinity of a first lateral surface portion of the gate electrode when viewed in a normal direction of the substrate and whose height from an upper surface of the oxide semiconductor layer is smaller than a height of an upper surface of the gate electrode and
a second fringe region which is located in a vicinity of a second lateral surface portion of the gate electrode when viewed in the normal direction of the substrate and whose height from the upper surface of the oxide semiconductor layer is smaller than the height of the upper surface of the gate electrode,
the porous insulator layer includes a first portion located in the first fringe region and a second portion located in the second fringe region, and each of the first portion and the second portion of the porous insulator layer is in contact with part of the oxide semiconductor layer which is not covered with the gate insulating layer, and
the step (B) includes steps of
(B1) forming an insulative film and an electrically-conductive gate film in this order on the oxide semiconductor layer,
(B2) patterning the electrically-conductive gate film using a first mask, thereby forming the gate electrode, and
(B4) after the step (B2), patterning the insulative film using the first mask or using the gate electrode as a mask, thereby forming the gate insulating layer, a lateral surface of the gate insulating layer being more internal than a lateral surface of the gate electrode when viewed in the normal direction of the substrate.

18. The method of claim 17, wherein the step (B3) includes performing isotropic etching of the insulative film using the first mask or using the gate electrode as a mask, thereby forming the gate insulating layer.

19. The method of claim 17, wherein the step (B3) includes
(B4) performing anisotropic etching on the insulative film using the first mask or using the Gate electrode as a mask, thereby forming a rate insulating layer precursor, and
(B5) etching a lateral surface of the gate insulating layer precursor, thereby forming the gate insulating layer.

20. The method of claim wherein the step (C) includes forming the porous insulator layer so as to be in contact with the lateral surface of the gate insulating layer.
